(19) United States
(12) Patent Application Publication
(10) Pub. No.: US 2024/0332175 A1
(43) Pub. Date: Oct. 3, 2024

(54) BACKSIDE TRANSISTOR CONTACT SURROUNDED BY OXIDE

(71) Applicant: Intel Corporation, Santa Clara, CA (US)

(72) Inventors: Joseph D’SILVA, Hillsboro, OR (US); Ehren MANNEBACH, Tigard, OR (US); Mauro J. KOBRINSKY, Portland, OR (US)

(21) Appl. No.: 18/129,400

(22) Filed: Mar. 31, 2023

(51) Int. Cl. H01L 23/528; H01L 21/8238; H01L 27/092; H01L 29/06; H01L 29/423; H01L 29/66; H01L 29/775; H01L 29/78; H01L 29/786

(52) U.S. Cl. CPC H01L 23/5283; H01L 21/823807; H01L 21/823821; H01L 21/823871; H01L 27/0924; H01L 29/0673; H01L 29/42392; H01L 29/66439; H01L 29/66795; H01L 29/775; H01L 29/7851; H01L 29/7869; H01L 29/78696

(57) ABSTRACT

Embodiments described herein may be related to apparatuses, processes, systems, and/or techniques for forming backside contacts on a transistor structure by forming, during front-side processing, trenches through the transistor structure into a silicon wafer, and then, using a catalytic oxidant material that is subsequently removed, forming an oxide structure in the silicon wafer around the trenches to isolate the backside gate contact from the source/drain trenches. Other embodiments may be described and/or claimed.

### FIELD

Embodiments of the present disclosure generally relate to the field of semiconductor manufacturing, and in particular forming contacts on a backside of a transistor layer.

### BACKGROUND

Continued growth in virtual machines, cloud computing, and portable devices will continue to increase the demand for high density transistors within chips and packages. In addition, there will be an increased need for high quality registration of electrical contacts to various structures within the transistor.

### BRIEF DESCRIPTION OF THE DRAWINGS

FIG. 1 shows an example gate cut view of a transistor layer that includes backside contacts that are surrounded by an oxide, in accordance with various embodiments.

FIGS. 2A-2F show a gate cut view and a fin cut view of various stages in the manufacturing of a transistor layer that includes backside contacts that are surrounded by an oxide, in accordance with various embodiments.

FIG. 3 illustrates an example process for manufacturing a transistor layer that includes backside contacts that are surrounded by an oxide, in accordance with various embodiments.

FIG. 4 illustrates a computing device in accordance with one implementation of the invention.

FIG. 5 illustrates an interposer that includes one or more embodiments of the invention.

### DETAILED DESCRIPTION

Embodiments described herein may be related to apparatuses, systems, processes, and/or techniques for forming tight-pitch contacts, connections, or electrical couplings to sources, drains, and/or gates on the backside of a transistor structure. In embodiments, these techniques may also be used to place tight pitch connections on the backside of a wafer. In embodiments, these connections may be referred to as backside contacts or as backside contact over active gate (BSCOAG). In embodiments, self-alignment techniques may be used which may be less susceptible to bonding distortions, and that allow scaling to tighter pitches. This may be because a liner is not used during the contact creation process, in comparison to legacy techniques that use liners during the contact creation process.

In embodiments, during front side processing, etchings may be performed through layers of a transistor structure and into a silicon wafer to create trenches, or cavities, in the silicon wafer. The silicon wafer may also be referred to as sub-fin material. The material of the silicon wafer around these cavities may then be oxidized, for example by insertion of a catalytic oxidation material followed by an annealing process, or through an oxygen implant using, for example, an ion beam implanting process. As a result, a silicon oxide layer may be formed in the silicon wafer. In embodiments, the catalytic oxidation material may be removed, and a conductive material, such as a metal, may be inserted into the trenches surrounded by the silicon oxide material to form a backside contact. Note that the creation of the silicon oxide layer may be done during front side processing of the transistor structure.

In embodiments, an epitaxial material may then be placed on top of the backside contact material to fill the rest of the trenches, to create sources and/or drains. During manufacture, the silicon wafer material around the silicon oxide layer may be removed, and one or more of the backside contacts may be exposed. In embodiments, after the silicon wafer material is removed, edge placement error can be increased through the use of an additional dielectric liner applied on the silicon oxide, or a portion of the silicon oxide reduced using a directional etch. These techniques also provide a way to block off the sources and drains when creating connections to the gates after the sub-fin material has been removed. Another conductive material, such as tungsten (W), may then be deposited to electrically couple with gates at the backside of the transistor structure.

Legacy implementations use a liner-based approach where the separate application of a liner is used prior to depositing the conductive material that will become the backside contacts. However, such legacy implementations will reach a scaling limit, because the liners require a minimum thickness to function as effective barriers to protect the backside contacts.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

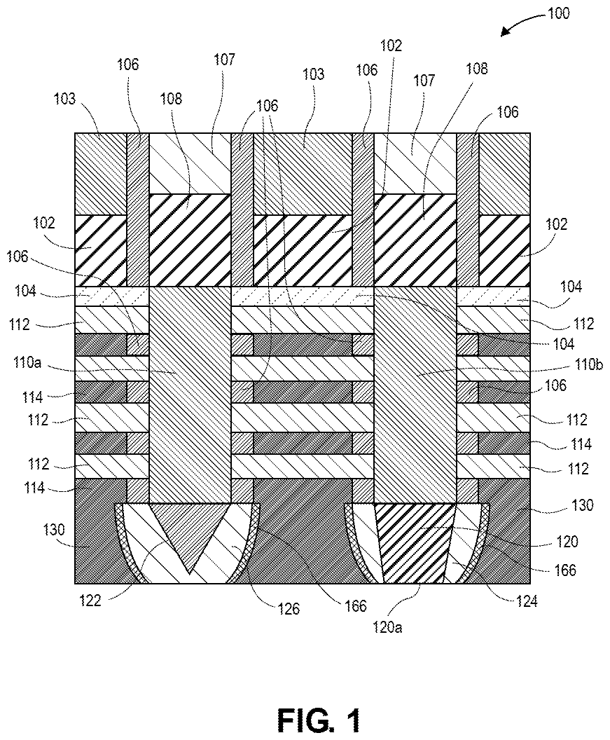

FIG. 1 shows an example gate cut view of a transistor layer that includes backside contacts that are surrounded by an oxide, in accordance with various embodiments. Partial transistor structure 100 shows a gate cut view that includes gate metal contacts 102, which may be composed of tungsten (W), that are on a gate dielectric 104. A gate interlayer dielectric 103 may be on top of the gate metal contacts 102. In embodiments, the gate interlayer dielectric 103 may include silicon nitride. Gate spacers 106 may at least partially surround the gate metal contacts 102 and may separate tungsten 114, which may be referred to as a gate metal, from epitaxial structures 110a and 110b. Trench connectors 108 may be between the gate spacers 106 and on top of the epitaxial structures 110a, 110b. Dielectric 107 may be on top of the trench connectors 108. The epitaxial structures 110a, 110b may extend through multiple layers of silicon 112 and tungsten 114, where the layers of silicon 112 may be transistor channels, and the tungsten 114 may be a gate metal. Gate spacers 106 may also be present between tungsten 114 and each of epitaxial structures 110a, 110b.

In embodiments, a backside contact 120 may be electrically coupled with the epitaxial structure 110a, and trench filler 122 may be electrically coupled with the epitaxial structure 110b. In embodiments, trench filler 122 may be any combination of a spacer material, remaining patterning materials, a fillable oxide, other dielectric materials, or conductive materials. In embodiments, the trench filler 122 may be a voids. A first region of silicon oxide 124, which may be referred to as an oxide layer, may surround at least a part of the backside contact 120 and a second region of silicon oxide 126, which may be referred to as an oxide layer, may surround the trench filler 122. In embodiments, a liner 166 may surround the first region of silicon oxide 124, and a liner 166 may surround the second region of silicon oxide 126. Note that a surface 120a of the backside contact 120 is exposed and is ready to be electrically coupled with additional electrically conductive routings in a backside interconnect layer (not shown). In embodiments the backside contact 120 may be a part of the backside interconnect layer (not shown). In embodiments, a backside gate contact 130, which may be a tungsten layer, may be placed on either side of the backside contact 120 and the trench filler 122, and may serve as a gate contact.

Embodiments may include a region of silicon oxide that isolates a backside source or drain contact from a backside gate contact 130, such as the first region of silicon oxide 124 that is parallel to the layers of silicon 112 and at the epitaxial structure 110b. Embodiments may also include a region of silicon oxide that isolates a front side source or drain structure from a backside gate contact 130, such as the second region of silicon oxide 126 that is parallel to the layers of silicon 112 and at the epitaxial structure 110a. The volume of the second region of silicon oxide 126 may be larger than a volume of the first region of silicon oxide 124 due to the presence of the backside contact through the area of the first region of silicon oxide 124. In embodiments, a size or an area of a first cross-section of the first region of silicon oxide 124 that is parallel to the layers of silicon 112 and at the epitaxial structure 110b at a first end of the backside contact 120 may be greater than a size or an area of a cross-section of the first region of the silicon oxide 124 that is parallel to the layers of silicon 112 at the surface 120a at a second end of the backside contact 120.

In embodiments, the interface between the first region of silicon oxide 124 and the liner 166 or the interface between the second region of silicon oxide 126 and the liner 166 will be consistent with the silicon oxide region resulting from the conversion of silicon to silicon oxide during the oxidation process described herein, and as a result and will contain neither the characteristic interface such as a seam, nor any chemical species that would be consistent with a deposited silicon oxide layer.

Note that the trench filler 122 is completely encased within the second region of silicon oxide 126. In embodiments, the first region of silicon oxide 124 and the second region of silicon oxide 126 may each be part of a monolithic structure and may not contain any seam, since these regions of silicon oxide are formed from conversion of original silicon structure into silicon oxide. It should be appreciated that although a nanoribbon structure is shown in partial transistor structure 100, other embodiments may include finFET transistor, nanowire transistor, nanocomb transistor, forksheet transistor, or planar transistor architectures.

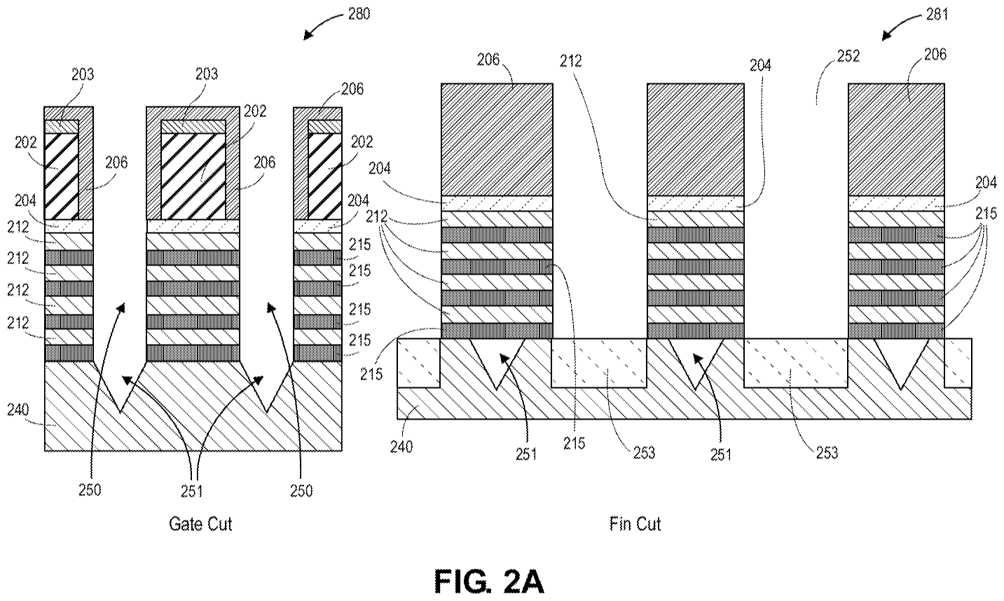

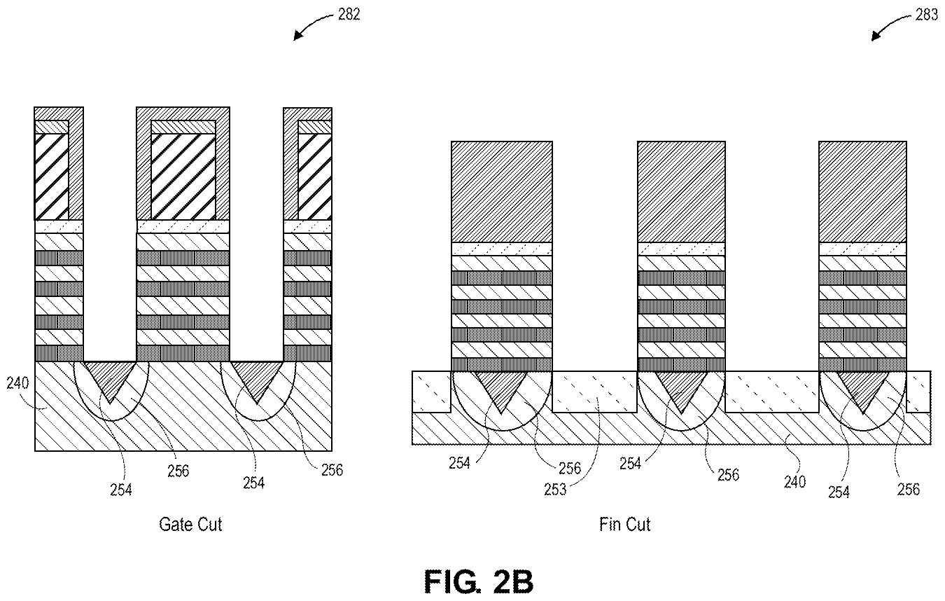

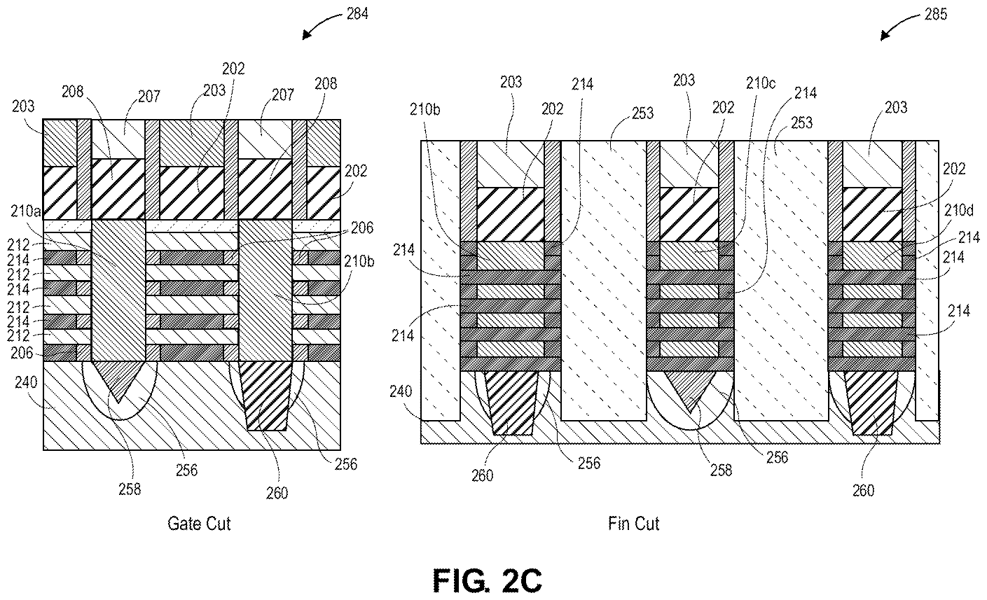

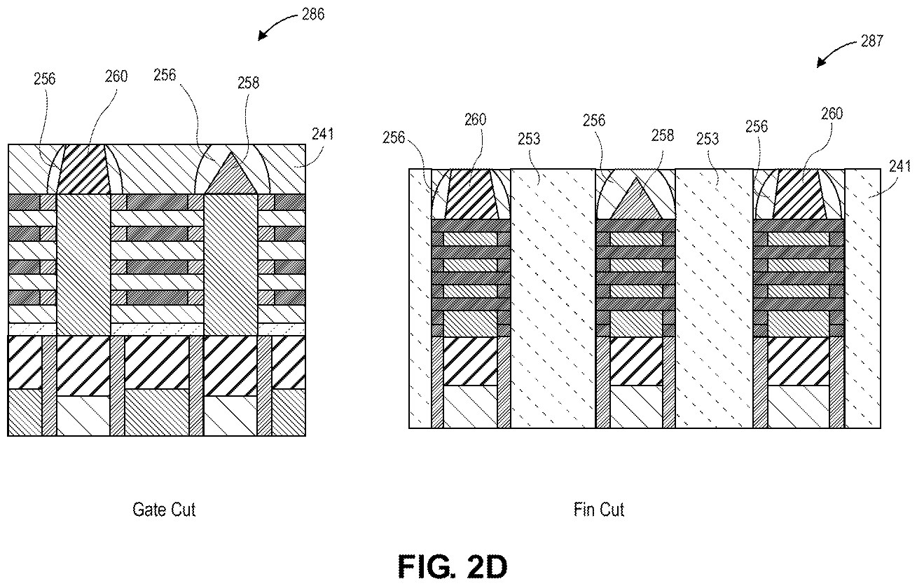

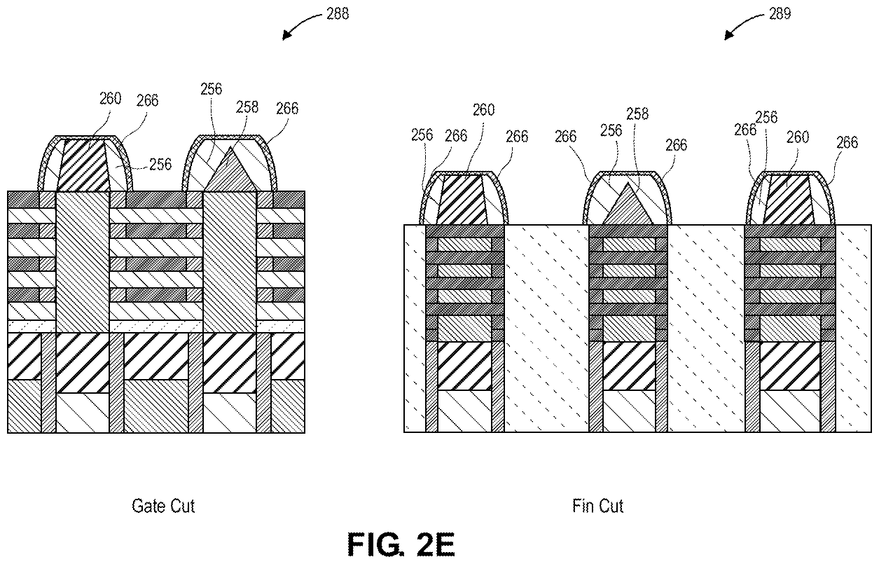

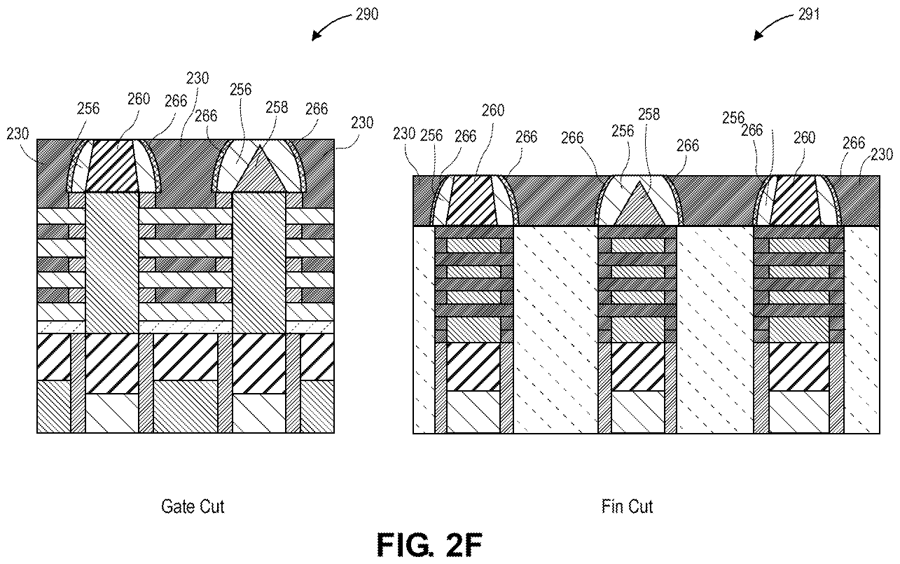

FIGS. 2A-2F show a gate cut view and a fin cut view of various stages in the manufacturing of a transistor layer that includes backside contacts that are surrounded by an oxide, in accordance with various embodiments. FIG. 2A shows a gate cut view 280 and a fin cut view 281 of a stage in the manufacturing process where a wafer 240 is provided. In embodiments, the wafer 240 may be a silicon wafer or may be a silicon substrate. In embodiments, layers of silicon germanium 215 and layers of silicon 212, which may be similar to layers of silicon 112 of FIG. 1, may be stacked on each other on top of the wafer 240 to form a part of a transistor structure, which may be similar to partial transistor structure 100 of FIG. 1.

In embodiments, a gate dielectric 204, which may be similar to gate dielectric 104 of FIG. 1, may be placed on top of the layers of silicon germanium 215 and the layers of silicon 212. Gates 202, which may be similar to gate metal contacts 102 of FIG. 1 or may be replacement poly gates, may be placed on the gate dielectric 204. A gate interlayer dielectric 203, which may be similar to gate interlayer dielectric 103 of FIG. 1, may be placed on the gates 202. In embodiments, a gate oxide 206, which may be similar to gate spacer 106 of FIG. 1, may at least partially surround the gate 202 and the gate interlayer dielectric 203.

In embodiments, cavities 250 may be formed through the gate dielectric 204, and the layers of silicon germanium 215 and the layers of silicon 212, at least partially into the wafer 240. In embodiments, the cavities 250 may correspond to an epitaxial structure for sources or drains in subsequent manufacturing stages. In embodiments, the cavities 250 may be formed using patterning and an etching process, such as a wet etch or a dry etch, and may be an anisotropic etch. As a result, trenches 251 within cavities 250 may be formed in the wafer 240. Fin cut view 281 shows a shallow trench isolation process has been performed, for example by using an etch, to create a cavity 252 that goes within the wafer 240, and a dielectric 253, which may be referred to as a shallow trench isolation (STI), may be placed into a portion of the cavity 252.

FIG. 2B shows a gate cut view 282 and a fin cut view 283 of a stage in the manufacturing process where a catalytic oxidation material 254 is placed into the trenches 251 in the wafer 240. In embodiments, the catalytic oxidation material 254 may be placed adjacent to and in physical contact with the wafer 240. In embodiments, the catalytic oxidation material 254 may include aluminum oxide. An annealing process may then occur to create an oxide formation 256 within the wafer 240 and surrounding the catalytic oxidation material 254. In embodiments, the catalytic oxidation material 254 may include silicon oxide (SiOx) when the wafer 240 is a silicon wafer. Note that in embodiments, the oxide formation 256 will not have a seam, but will be a contiguous formation. In other embodiments, instead of a catalytic oxidation material 254, a plasma implant process or a beam-line implant process may be used to deposit oxygen atoms within the wafer 240 followed by an anneal to create the oxide formation 256.

FIG. 2C shows a gate cut view 284 and a fin cut view 285 of a stage in the manufacturing process where the catalytic oxidation material 254 of FIG. 2B is removed, and front side processing may continue. In embodiments, the catalytic oxidation material 254 of FIG. 2B is removed. A trench filler 258, which may be similar to trench filler 122 of FIG. 1, may be formed within the wafer 240 and within the oxide formation 256. Backside contact 260, which may be referred to as a sacrificial backside contact placeholder and/or which may be similar to backside contact 120 of FIG. 1, may be placed within the wafer 240, where the oxide formation 256 may partially surround the backside contacts 260. Note that additional etching of the wafer 240 may be required in order to form the backside contacts 260.

In embodiments, the layers of silicon germanium 215 may be removed using an etch process, and may be replaced with tungsten layers 214. In embodiments, the tungsten layers 214 may serve as gate-all-around for the partial transistor structure 100 of FIG. 1. In embodiments, the tungsten layers 214 can be any metal stack than can function as gate-all-around.

In embodiments, a first epitaxial structure 210a, a second epitaxial structure 210b, which may be similar to first epitaxial structure 110a and second epitaxial structure 110b of FIG. 1, may then be formed, and may be directly coupled with the trench filler 258 and the backside contacts 260. Epitaxial structures 210b, 210c, 210d may also be formed. Trench connectors 208 may then be placed on top of the epitaxial structures 210a, and a dielectric 207, which may be similar to dielectric 107 of FIG. 1, may be placed on top of the trench connectors 208.

FIG. 2D shows a gate cut view 286 and a fin cut view 287 of a stage in the manufacturing process where wafer 240 is ground to form wafer 241, where a portion of the backside contact 260 is exposed. The backside contact 260 will be at least partially surrounded by oxide formation 256. In embodiments, the trench filler 258 may not be exposed, and may continue to be completely surrounded by the oxide formation 256. Note that gate cut view 286 and fin cut view 287 are flipped as compared to gate cut view 284 and fin cut view 285 of FIG. 2C.

FIG. 2E shows a gate cut view 288 and a fin cut view 289 of a stage in the manufacturing process where the wafer 241 of FIG. 2D is ground to reveal the dielectric 253, or shallow trench isolation, and in embodiments the wafer 241, which may be referred to as the silicon sub-fin, may be removed by etch. A liner 266 may be placed around the oxide formation 256. In embodiments, the liner 266 may also cover the top of the backside contact 260. In embodiments, at this stage in the manufacturing process, prior to the application of the liner 266, the various oxide formations 256 may be adjusted, for example to make sure that the oxide formations 256 isolate the epitaxial structures 210a, 210b. The oxide formations 256 may be added through the deposition of additional oxide liners (not shown), or may be reduced by using a directional etch.

FIG. 2F shows a gate cut view 290 and a fin cut view 291 of a stage in the manufacturing process where a tungsten layer 230 is applied to form a backside gate contact, which may be similar to backside gate contact 130 of FIG. 1. In embodiments, the tungsten layers 230 may be some other appropriate gate metal layer or gate metal layer stack.

FIGS. 2A-2F illustrate an embodiment of creating a backside gate contact, similar techniques may be used to create a backside gate to source, or a backside gate to drain connection. For example, a gate to source connection may be created by only oxidizing the sub-fin under a drain trench on the front side, instead of oxidizing the sub-fin under both source and drain trenches.

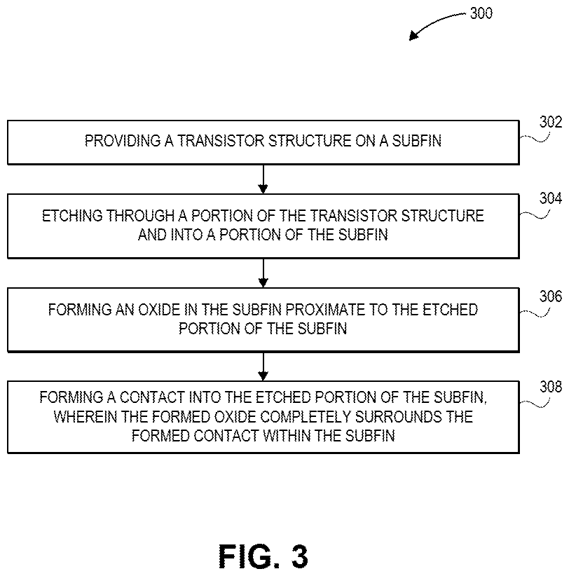

FIG. 3 illustrates an example process for manufacturing a transistor layer that includes backside contacts that are surrounded by an oxide, in accordance with various embodiments. In embodiments, process 300 may be performed using the apparatus, systems, processes, or techniques described herein, and in particular with respect to FIGS. 1-2F.

At block 302, the process may include providing a transistor structure on a sub-fin. In embodiments, the transistor structure may be similar to partial transistor structure 100 of FIG. 1.

At block 304, the process may further include etching through a portion of the transistor structure and into a portion of the sub-fin. In embodiments, the etching may be similar to the process used to create cavities 250 of FIG. 2A.

At block 306, the process may further include forming an oxide in the sub-fin proximate to the etched portion of the sub-fin. In embodiments, the sub-fin may be similar to wafer 240 of FIG. 2B. In embodiments, the formed oxide may be similar to oxide formation 256 of FIG. 2B.

At block 308, the process may further include forming a contact into the etched portion of the sub-fin, wherein the formed oxide completely surrounds the formed contact within the sub-fin. In embodiments, the formed contact may be similar to contact 260 of FIGS. 2C-2F.

Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or all-around-gate transistors such as nanoribbon transistor and/or nanowire transistor. Although the implementations described herein may illustrate only planar transistors, it should be noted that the invention may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

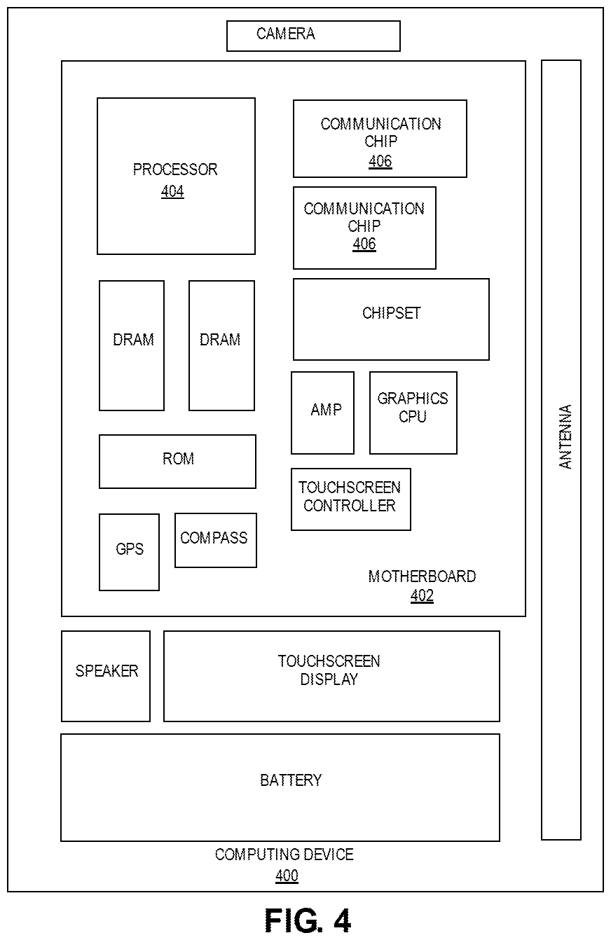

FIG. 4 illustrates a computing device 400 in accordance with one implementation of the invention. The computing device 400 houses a board 402. The board 402 may include a number of components, including but not limited to a processor 404 and at least one communication chip 406. The processor 404 is physically and electrically coupled to the board 402. In some implementations the at least one communication chip 406 is also physically and electrically coupled to the board 402. In further implementations, the communication chip 406 is part of the processor 404.

Depending on its applications, computing device 400 may include other components that may or may not be physically and electrically coupled to the board 402. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 406 enables wireless communications for the transfer of data to and from the computing device 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 406 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 400 may include a plurality of communication chips 406. For instance, a first communication chip 406 may be dedicated to shorter range wireless communications such as Wi-Fi and Bluetooth and a second communication chip 406 may be dedicated to longer range wireless communications such as GPS, EDGE, GPRS, CDMA, WiMAX, LTE, Ev-DO, and others.

The processor 404 of the computing device 400 includes an integrated circuit die packaged within the processor 404. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 406 also includes an integrated circuit die packaged within the communication chip 406. In accordance with another implementation of the invention, the integrated circuit die of the communication chip includes one or more devices, such as MOS-FET transistors built in accordance with implementations of the invention.

In further implementations, another component housed within the computing device 400 may contain an integrated circuit die that includes one or more devices, such as MOS-FET transistors built in accordance with implementations of the invention.

In various implementations, the computing device 400 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 400 may be any other electronic device that processes data.

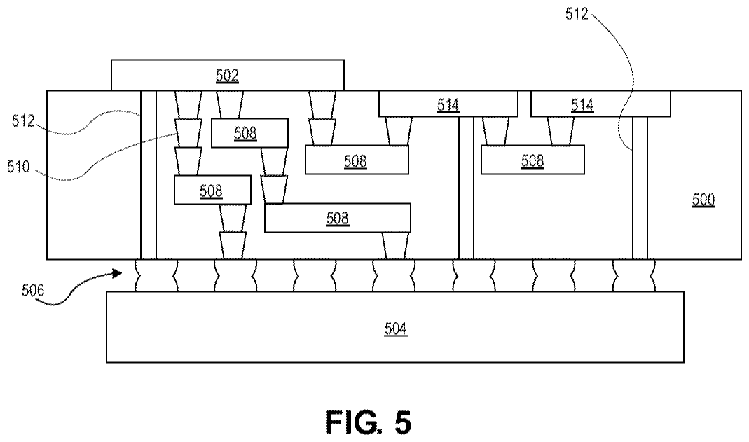

FIG. 5 illustrates an interposer 500 that includes one or more embodiments of the invention. The interposer 500 is an intervening substrate used to bridge a first substrate 502 to a second substrate 504. The first substrate 502 may be, for instance, an integrated circuit die. The second substrate 504 may be, for instance, a memory module, a computer motherboard, or another integrated circuit die. Generally, the purpose of an interposer 500 is to spread a connection to a wider pitch or to reroute a connection to a different connection. For example, an interposer 500 may couple an integrated circuit die to a ball grid array (BGA) 506 that can subsequently be coupled to the second substrate 504. In some embodiments, the first and second substrates 502/504 are attached to opposing sides of the interposer 500. In other embodiments, the first and second substrates 502/504 are attached to the same side of the interposer 500. And in further embodiments, three or more substrates are interconnected by way of the interposer 500.

The interposer 500 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 508 and vias 510, including but not limited to through-silicon vias (TSVs) 512. The interposer 500 may further include embedded devices 514, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 500. In accordance with embodiments of the invention, apparatuses or processes disclosed herein may be used in the fabrication of interposer 500.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

The following paragraphs describe examples of various embodiments.

### EXAMPLES

Example 1 is a package comprising: a transistor structure; an epitaxial structure that extends through the transistor structure to an interconnect layer at a backside of the transistor structure; a first end of a contact directly physically coupled with an end of the epitaxial structure, wherein the contact has a second end opposite the first end and a side between the first end and the second end; and an oxide layer directly physically coupled with the side of the contact.

Example 2 includes the package of example 1, wherein the oxide layer is directly physically coupled with and completely surrounds the second end of the contact.

Example 3 includes the package of examples 1 or 2, further comprising: a liner surrounding the oxide layer; and wherein the oxide layer does not include a seam.

Example 4 includes the package of examples 1, 2, or 3, wherein a first side of the oxide layer is directly physically coupled with the side of the contact.

Example 5 includes the package of examples 1, 2, 3, or 4, wherein the contact includes a selected one or more of: silicon (Si), oxygen (O), nitrogen (N), titanium (Ti), molybdenum (Mo), tungsten (W), aluminum (Al), lanthanum (La), magnesium (Mg), nickel (Ni), platinum (Pt), tantalum (Ta), ruthenium (Ru), and/or copper (Cu).

Example 6 includes the package of examples 1, 2, 3, 4, or 5, wherein the contact is within the interconnect layer at the backside of the transistor structure.

Example 7 includes the package of examples 1, 2, 3, 4, 5, or 6, further including a liner on the oxide layer, wherein the liner includes a selected one or more of: silicon, nitrogen, oxygen, aluminum, hafnium, silicon nitride (SiN), silicon oxide (SiOx), aluminum oxide (AlOx), and/or hafnium oxide (HfOx).

Example 8 includes the package of examples 1, 2, 3, 4, 5, 6, or 7, wherein the oxide layer is at least partially surrounded by a selected one or more of: tungsten (W), titanium (Ti), molybdenum (Mo), aluminum (Al), lanthanum (La), magnesium (Mg), nickel (Ni), platinum (Pt), tantalum (Ta), ruthenium (Ru), and/or copper (Cu).

Example 9 is a package comprising: a first transistor structure and a second transistor structure; a first epitaxial structure that extends through the first transistor structure to an interconnect layer at a backside of the first transistor structure; a second epitaxial structure that extends through the second transistor structure to the interconnect layer at a backside of the second transistor structure; a first contact directly electrically coupled with the first epitaxial structure and directly electrically coupled with the interconnect layer; a second contact directly electrically coupled with the second epitaxial structure and directly electrically coupled with the interconnect layer; a first oxide layer on a side of the first contact, wherein the first oxide layer is directly physically coupled with the side of the first contact; and a second oxide layer on a side of the second contact, wherein the second oxide layer is directly physically coupled with the side of the second contact.

Example 10 includes the package of example 9, wherein the first oxide layer or the second oxide layer does not include a seam.

Example 11 includes the package of examples 9 or 10, wherein the first contact and the second contact are electrically coupled with each other.

Example 12 includes the package of examples 9, 10, or 11, wherein the first epitaxial structure is electrically coupled with a first source or a first drain, and wherein the second epitaxial structure is electrically coupled with a second source or a second drain.

Example 13 includes the package of examples 9, 10, 11, or 12, further comprising a first liner directly physically coupled with the first oxide layer and a second liner directly physically coupled with the second oxide layer, wherein the first liner or the second liner includes a selected one or more of: silicon, nitrogen, oxygen, aluminum, hafnium, silicon nitride (SiN), silicon oxide (SiOx), aluminum oxide (AlOx), and/or hafnium oxide (HfOx).

Example 14 includes the package of example 13, wherein the first liner or the second liner are not directly physically coupled with the first contact or the second contact.

Example 15 includes the package of examples 9, 10, 11, 12, 13, or 14, wherein the first transistor structure or the second transistor structure is a selected one of: a finFET transistor, a nanowire transistor, a nanoribbon transistor, a nanocomb transistor, a forksheet transistor, or a planar transistor.

Example 16 is a method comprising: providing a transistor structure on a sub-fin; etching through a portion of the transistor structure and into a portion of the sub-fin; forming an oxide in the sub-fin proximate to the etched portion of the sub-fin; and forming a contact into the etched portion of the sub-fin, wherein the formed oxide completely surrounds the formed contact within the sub-fin.

Example 17 includes the method of example 16, wherein forming the oxide in the sub-fin proximate to the etched portion of the sub-fin further includes: placing a catalytic oxidant material in the etched portion of the sub-fin; and applying an annealing process.

Example 18 includes the method of examples 16 or 17, wherein the contact is a selected one or more of: silicon (Si), oxygen (O), nitrogen (N), titanium (Ti), molybdenum (Mo), tungsten (W), aluminum (Al), lanthanum (La), magnesium (Mg), nickel (Ni), platinum (Pt), tantalum (Ta), ruthenium (Ru), and/or copper (Cu).

Example 19 includes the method of examples 16, 17, or 18, further comprising placing an epitaxial material in the etched portion of the transistor structure, wherein the epitaxial material is directly coupled with the contact.

Example 20 includes the method of example 16, 17, 18, or 19, further comprising: electrically coupling the contact with an interconnect layer at a backside of the transistor structure.

Example 21 includes the method of example 16, 17, 18, 19, or 20, wherein forming the oxide in the sub-fin proximate to the etched portion of the sub-fin further includes: placing a catalytic oxidant material in the etched portion of the sub-fin; and annealing or applying a plasma implant process or beam-line implant process to the sub-fin trench and annealing.

Example 22 is a package comprising: a transistor structure; an epitaxial structure that extends through the transistor structure to an interconnect layer at a backside of the transistor structure and/or an epitaxial structure that extends through the transistor structure ending above a dielectric-filled trench that extends into the substrate; a first end of a contact directly physically coupled with an end of the epitaxial structure, wherein the contact has a second end opposite the first end and a side between the first end and the second end; and an oxide layer directly physically coupled with the side of the contact, wherein the oxide layer does not include a seam.

Example 23 includes the package of example 22, wherein a first side of the oxide layer is directly physically coupled with the side of the contact, wherein a second side of the oxide layer is opposite the first side, and wherein a size of a first cross-section of the oxide layer parallel to a plane of the transistor structure at the first end of the contact is larger than a size of a second cross-section of the oxide layer parallel to the plane of the transistor structure at the second end of the contact. (i) in the case of a source/drain connected to a backside interconnect, the oxide layer surrounds the sides of the contact is directly physically coupled to the side surfaces (surface normal is parallel to the fins/ribbons) of the contact and (ii) in the case of a source/drain trench that is not connected to a backside interconnect, the oxide layer completely surrounds the portion of the source drain trench that extends into the substrate.

Example 24 is a package comprising: a first transistor structure and a second transistor structure; a first epitaxial structure that extends through the first transistor structure to an interconnect layer at a backside of the first transistor structure; a second epitaxial structure that extends through the second transistor structure to the interconnect layer at a backside of the second transistor structure into a trench etched into the sub-fin; a first contact directly electrically coupled with the first epitaxial structure and directly electrically coupled with the backside interconnect layer; a second contact directly electrically coupled with the second epitaxial structure and directly electrically coupled with the interconnect layer and electrically connected to a front side interconnect layer; a first oxide layer on a side of the first contact, wherein the first oxide layer is directly physically coupled with the side of the first contact; and a second oxide layer on a side of the second contact, wherein the second oxide layer is directly physically coupled with the side of the second contact and surrounding the trench underneath the epitaxial layer of the first transistor such that it would prevent electrical contact to the epitaxial layer.

Example 25 includes the package of example 24, wherein the first oxide layer or the second oxide layer does not include a seam.

Example 26 includes the package of examples 24 or 25, wherein the first contact and the second contact are electrically coupled with each other.

Example 27 includes the package of examples 24, 25, or 26, wherein the first epitaxial structure is electrically coupled with a first source or a first drain, and wherein the second epitaxial structure is electrically coupled with a second source or a second drain.

Example 28 includes the package of examples 24, 25, 26, or 27, further comprising a first liner directly physically coupled with the first oxide layer and a second liner directly physically coupled with the second oxide layer, wherein the first liner or the second liner includes a selected one or more of: silicon nitride (SiN), silicon oxide (SiOx), aluminum oxide (AlOx), and/or hafnium oxide (HfOx).

Example 29 includes the package of example 28, wherein the first liner or the second liner are not directly physically coupled with the first contact or the epitaxial layer.

What is claimed is:

1. A package comprising:
a transistor structure;
an epitaxial structure that extends through the transistor structure to an interconnect layer at a backside of the transistor structure;
a first end of a contact directly physically coupled with an end of the epitaxial structure, wherein the contact has a second end opposite the first end and a side between the first end and the second end; and
an oxide layer directly physically coupled with the side of the contact.

2. The package of claim 1, wherein the oxide layer is directly physically coupled with and completely surrounds the second end of the contact.

3. The package of claim 1, further comprising:
a liner surrounding the oxide layer; and
wherein the oxide layer does not include a seam.

4. The package of claim 1, wherein a first side of the oxide layer is directly physically coupled with the side of the contact.

5. The package of claim 1, wherein the contact includes a selected one or more of: silicon (Si), oxygen (O), nitrogen (N), titanium (Ti), molybdenum (Mo), tungsten (W), aluminum (Al), lanthanum (La), magnesium (Mg), nickel (Ni), platinum (Pt), tantalum (Ta), ruthenium (Ru), and/or copper (Cu).

6. The package of claim 1, wherein the contact is within the interconnect layer at the backside of the transistor structure.

7. The package of claim 1, further including a liner on the oxide layer, wherein the liner includes a selected one or more of: silicon, nitrogen, oxygen, aluminum, hafnium, silicon nitride (SiN), silicon oxide (SiOx), aluminum oxide (AlOx), and/or hafnium oxide (HfOx).

8. The package of claim 1, wherein the oxide layer is at least partially surrounded by a selected one or more of: tungsten (W), titanium (Ti), molybdenum (Mo), aluminum (Al), lanthanum (La), magnesium (Mg), nickel (Ni), platinum (Pt), tantalum (Ta), ruthenium (Ru), and/or copper (Cu).

9. A package comprising:
a first transistor structure and a second transistor structure;
a first epitaxial structure that extends through the first transistor structure to an interconnect layer at a backside of the first transistor structure;
a second epitaxial structure that extends through the second transistor structure to the interconnect layer at a backside of the second transistor structure;
a first contact directly electrically coupled with the first epitaxial structure and directly electrically coupled with the interconnect layer;
a second contact directly electrically coupled with the second epitaxial structure and directly electrically coupled with the interconnect layer;
a first oxide layer on a side of the first contact, wherein the first oxide layer is directly physically coupled with the side of the first contact; and
a second oxide layer on a side of the second contact, wherein the second oxide layer is directly physically coupled with the side of the second contact.

10. The package of claim 9, wherein the first oxide layer or the second oxide layer does not include a seam.

11. The package of claim 9, wherein the first contact and the second contact are electrically coupled with each other.

12. The package of claim 9, wherein the first epitaxial structure is electrically coupled with a first source or a first drain, and wherein the second epitaxial structure is electrically coupled with a second source or a second drain.

13. The package of claim 9, further comprising a first liner directly physically coupled with the first oxide layer and a second liner directly physically coupled with the second oxide layer, wherein the first liner or the second liner includes a selected one or more of: silicon, nitrogen, oxygen, aluminum, hafnium, silicon nitride (SiN), silicon oxide (SiOx), aluminum oxide (AlOx), and/or hafnium oxide (HfOx).

14. The package of claim 13, wherein the first liner or the second liner are not directly physically coupled with the first contact or the second contact.

15. The package of claim 9, wherein the first transistor structure or the second transistor structure is a selected one of: a finFET transistor, a nanowire transistor, a nanoribbon transistor, a nanocomb transistor, a forksheet transistor, or a planar transistor.

16. A method comprising:
providing a transistor structure on a sub-fin;
etching through a portion of the transistor structure and into a portion of the sub-fin;
forming an oxide in the sub-fin proximate to the etched portion of the sub-fin; and
forming a contact into the etched portion of the sub-fin, wherein the formed oxide completely surrounds the formed contact within the sub-fin.

17. The method of claim 16, wherein forming the oxide in the sub-fin proximate to the etched portion of the sub-fin further includes:
placing a catalytic oxidant material in the etched portion of the sub-fin; and
applying an annealing process.

18. The method of claim 16, wherein the contact is a selected one or more of: silicon (Si), oxygen (O), nitrogen (N), titanium (Ti), molybdenum (Mo), tungsten (W), aluminum (Al), lanthanum (La), magnesium (Mg), nickel (Ni), platinum (Pt), tantalum (Ta), ruthenium (Ru), and/or copper (Cu).

19. The method of claim 16, further comprising placing an epitaxial material in the etched portion of the transistor structure, wherein the epitaxial material is directly coupled with the contact.

20. The method of claim 16, further comprising: electrically coupling the contact with an interconnect layer at a backside of the transistor structure.
